(19) United States
(12) Patent Application Publication
(10) Pub. No.: US 2013/0264599 A1
(43) Pub. Date: Oct. 10, 2013

(54) SEMICONDUCTOR MODULE

(71) Applicant: PANASONIC CORPORATION, Osaka (JP)

(72) Inventors: Masato KIKUCHI, Kyoto (JP); Satoru WAGA, Kyoto (JP)

(73) Assignee: PANASONIC CORPORATION

(21) Appl. No.: 13/911,859

(22) Filed: Jun. 6, 2013

Related U.S. Application Data
(63) Continuation of application No. PCT/JP2011/003982, filed on Jul. 12, 2011.

(30) Foreign Application Priority Data
Jan. 7, 2011 (JP) 2011-002207

(51) Int. Cl. H01L 33/48; H01L 31/02

(52) U.S. Cl. CPC H01L 33/48; H01L 31/02
USPC 257/98; 257/433

(57) ABSTRACT

The purpose is the overall miniaturization of a product in which a semiconductor module is mounted. Provided is a semiconductor module including a first semiconductor chip that has an optical element, second semiconductor chip that is mounted over the first semiconductor chip, a casing having an opening, the first semiconductor chip and the second semiconductor chip being accommodated inside the casing and the opening being at a position corresponding to the optical element, and a light-transmitting cover that closes the opening of the casing. In the above-mentioned structure, the second semiconductor chip is provided with a reflection suppressing function.

### CROSS REFERENCE TO RELATED APPLICATION

This is a continuation application of PCT Application No. PCT/JP2011/003982 filed Jul. 12, 2011, designating the United States of America, the disclosure of which, including the specification, drawings and claims, is incorporated herein by reference in its entirety.

### TECHNICAL FIELD

The present disclosure relates to a semiconductor module having a package casing and semiconductor chips accommodated therein, and, in particular, to a miniaturization technology for a semiconductor module.

### DESCRIPTION OF THE RELATED ART

One example of a conventional semiconductor module has a package casing and a semiconductor chip such as a solid-state image-pickup element accommodated therein. For example, Patent Literature 1 discloses a semiconductor module provided with a solid-state image-pickup element and a light-transmitting protection plate. The solid-state image-pickup element is mounted inside a package casing with an opening, and the light-transmitting protection plate closes the opening. This solid-state image-pickup element includes photoelectric conversion units for converting light into electricity, and the photoelectric conversion units are arranged so as to face the light-transmitting protection plate. Light coming through the light-transmitting protection plate is incident on the photoelectric conversion units of the solid-state image-pickup element.

In addition, Patent Literature 2 and Patent Literature 3 disclose other exemplary semiconductor modules.

### CITATION LIST

### Patent Literature

### [Patent Literature 1]

Japanese Patent Application Publication No. 06-252371

### [Patent Literature 2]

Japanese Patent Application Publication No. 2002-354200

### [Patent Literature 3]

Japanese Patent Application Publication No. 62-196979

### SUMMARY

Although the above-mentioned semiconductor module includes the solid-state image-pickup element (i.e., first semiconductor chip) having optical elements such as photoelectric conversion units, the semiconductor module does not include a drive circuit (second semiconductor chip) for driving the optical element. Therefore, for example, in the case of a digital still camera, an additional workload is placed on manufacturers when implementing a semiconductor module, because the second semiconductor chip needs to be separately implemented outside the above-mentioned semiconductor module. Furthermore, another problem is that the overall miniaturization is difficult for a product having the semiconductor module mounted thereon.

In order to solve the above-mentioned problems, a semiconductor module according to the present disclosure is a semiconductor module including a first semiconductor chip having an optical element mounted thereon, a second semiconductor chip mounted over the first semiconductor chip, a casing accommodating therein the first semiconductor chip and the second semiconductor chip and having an opening at a position corresponding to the optical element, and a light-transmitting cover closing the opening of the casing. In the above-mentioned structure, the second semiconductor chip has a reflection suppressing function of suppressing reflection of light incident thereon.

With the above structure of semiconductor module described above, an advantage is provided that the overall miniaturization of a product having the semiconductor module mounted thereon is achieved by accommodating the first semiconductor chip and the second semiconductor chip in a single package.

In addition, the semiconductor module described above has a function for suppressing the light reflection from the second semiconductor chip to the optical element of the first semiconductor chip. This function provides another advantage that functional degradation due to unwanted light (e.g., image abnormality such as ghost and flare) is suppressed.

The general and specific aspects may be implemented using a manufacturing method.

Additional benefits and advantages of the disclosed embodiments will be apparent from the specification and figures. The benefits and/or advantages may be individually provided by various embodiments and features of the specification and drawings disclosed, and need not all be provided in order to obtain one or more of the same.

### BRIEF DESCRIPTION OF DRAWINGS

FIGS. 1A to 1D illustrate the structure of a semiconductor module according to an embodiment of the present disclosure.

FIGS. 2A to 2C illustrate the structure of a semiconductor module according to Variation 1 of the embodiment of the present disclosure.

FIGS. 3A to 3C illustrate the structure of a semiconductor module according to Variation 1 of the embodiment of the present disclosure. FIGS. 4A to 4C are reference drawings for explaining an effect obtained by forming a reflection suppressing portion on a side surface of a semiconductor chip.

FIGS. 5A to 5C illustrate the structure of a semiconductor module according to Variation 2 of the embodiment of the present disclosure.

FIGS. 6A to 6C illustrate the structure of a semiconductor module according to Variation 3 of the embodiment of the present disclosure.

FIGS. 7A to 7C illustrate the structure of a semiconductor module according to Variation 4 of the embodiment of the present disclosure. FIGS. 8A to 8C illustrate the structure of a semiconductor module according to Variation 5 of the embodiment of the present disclosure.

FIGS. 9A to 9C illustrate the structure of a semiconductor module according to Variation 6 of the embodiment of the present disclosure.

### DESCRIPTION OF EMBODIMENTS

The following describes an embodiment for implementing the present disclosure in detail, with reference to the drawings.

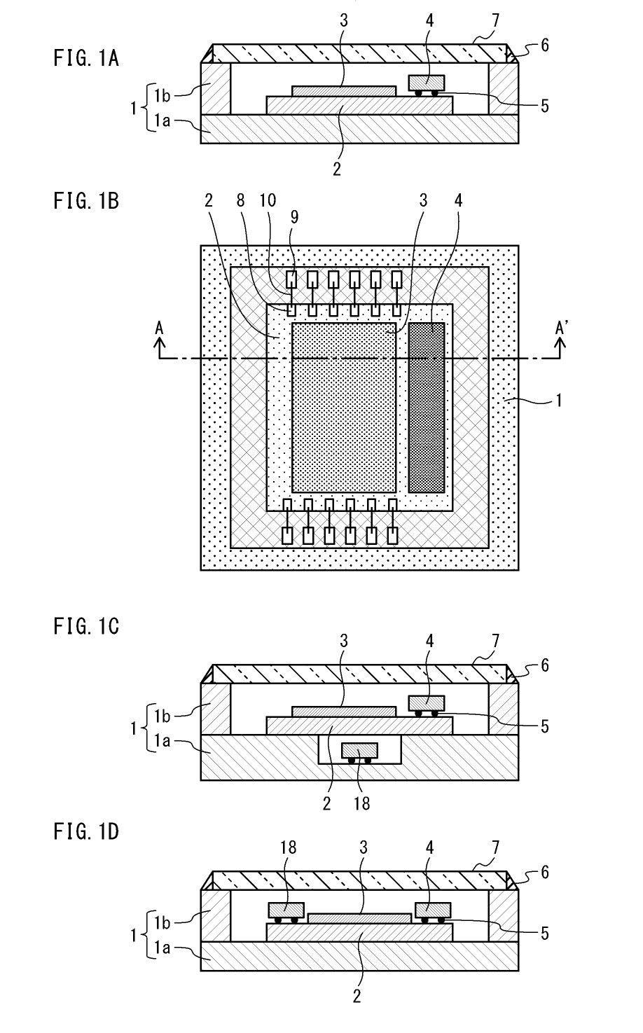

First, the general structure of a semiconductor module according to the embodiment of the present disclosure is described with reference to FIG. 1A to FIG. 1D.

(General Structure)

FIG. 1A is a schematic sectional view of the semiconductor module. FIG. 1B is a top view of the semiconductor module, shown with some parts removed for explaining the internal structure thereof. The semiconductor module includes, as major structural elements, a first semiconductor chip 2, a second semiconductor chip 4, a casing 1, and a light-transmitting cover 7.

FIG. 1B shows the semiconductor module with the light-transmitting cover 7 removed. The cross section shown in FIG. 1A is an arrow sectional view taken along the line A-A′ shown in FIG. 1B.

(Package)

A package is formed by (i) accommodating the first and second semiconductor chips 2 and 4 in an internal space defined in the casing 1 opening through an opening and (ii) closing the opening with the light-transmitting cover 7. The casing 1 is composed of a plate-like bottom portion 1a and a lateral portion 1b like a frame. The casing 1 is made of a ceramic material or the like. The bottom portion 1a and the lateral portion 1b may be separately molded and then bonded together, or may be molded as a single part. The casing 1 is provided with a plurality of electrode pads 9. The first semiconductor chip 2 also has a plurality of electrode pads 8 formed thereon, which are electrically connected, via wires 10, to the electrode pads 9 formed on the casing 1. Thus, electrical signals from the first semiconductor chip 2 are transmitted to the wiring external to the package via the electrode pads 9.

The light-transmitting cover 7 has a plate-like shape and made of light-transmitting resin, light-transmitting glass, or the like. The light-transmitting cover 7 is bonded to a top surface of the casing 1 using an adhesive 6 made of resin or the like, so as to close the opening which opens to the internal space of the casing 1. Note that the light-transmitting cover 7 may be fitted against the casing 1 at the lateral portion 1b thereof via a rubber material.

(Semiconductor Chip)

The first semiconductor chip 2 functions as a device including an optical element 3 which is a photo-detector or a light emitter. The photo-detector is an image sensor, optical pickup, or the like including at least one photoelectric conversion unit. The light emitter is a semiconductor laser, LED element, or the like.

When the first semiconductor chip 2 functions as an image sensor, the first semiconductor chip 2 includes a silicon substrate with a lens layer and a plurality of electrode pads mounted thereon. The silicon substrate further has, within a region thereof, a matrix of photoelectric conversion units for receiving incident light and converting the received light into electricity.

The second semiconductor chip 4 is provided with at least one of (i) a drive circuit for driving the optical element 3 formed on the first semiconductor chip 2 and (ii) a signal processing circuit for processing signals generated by the optical element 3 of the first semiconductor chip 2. The semiconductor chip 4 is flip-chip bonded to the semiconductor chip 2 via bumps 5. Flip-chip bonding provides an advantage that the surface area of the semiconductor chip 2 is reduced.

Preferably, the second semiconductor chip 4 should be arranged so as not to overlap the optical element 3 of the first semiconductor chip 2 when seen in plan view for the following reason. That is, when the second semiconductor chip 4 is arranged so as to overlap the optical element 3, sufficient performance as an optical element may not be achieved due to performance degradation proportional to the overlapped area. Yet, the second semiconductor chip 4 may be arranged so as to partially overlap the optical element 3.

As described above, the semiconductor module according to the embodiment of the present disclosure has a structure in which the first semiconductor chip including the optical element and the second semiconductor chip mounted on the first semiconductor chip for processing signals are accommodated in a single package. With this structure, the semiconductor module advantageously achieves overall miniaturization of a product having the semiconductor module mounted thereon.

Note that, although the semiconductor module in the above description of the embodiment includes two semiconductor chips, the number of semiconductor chips may be three or more, as long as at least one of the semiconductor chips is mounted on another semiconductor chip. For example, a third semiconductor chip 18 may be further mounted in a recess formed in the bottom portion of the casing 1 (i.e., under the bottom surface of the first semiconductor chip), in addition to the second semiconductor chip 4 which is mounted on the surface the first semiconductor chip 2 including the optical element 3 and mounted on the bottom portion of the casing 1 (see FIG. 1C). Alternatively, as shown in FIG. 1D, the third semiconductor chip 18 may be mounted on the surface of the first semiconductor chip 2, as is the second semiconductor chip 4. Here, the third semiconductor chip 18 may be a chip having an image processing function.

(Variation 1)

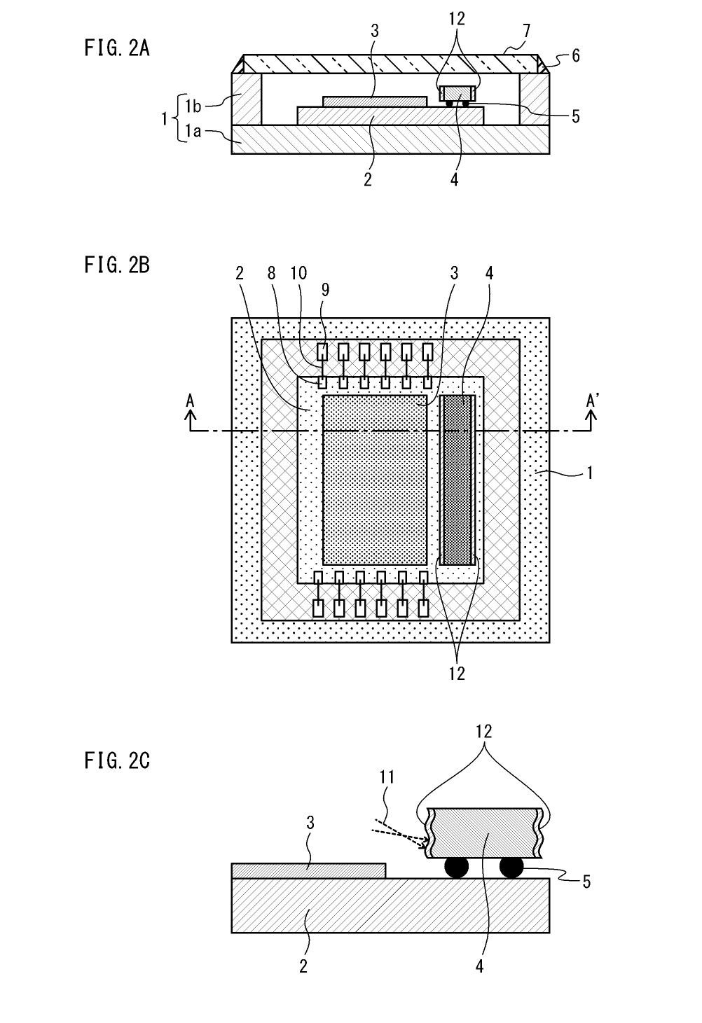

The following describes the general structure of a semiconductor module according to Variation 1 of the embodiment of the present disclosure with reference to FIG. 2A to FIG. 2C. FIG. 2A is a schematic sectional view of the semiconductor module. FIG. 2B is a top view showing the semiconductor module with the light-transmitting cover removed. FIG. 2C is a partially enlarged view of the semiconductor module showing the second semiconductor chip facing the optical element and other elements in vicinity thereof.

The structural elements in Variation 1 are the same as those in the embodiment except the second semiconductor chip 4. Therefore, description is omitted for the structural elements other than the second semiconductor chip 4, and the following describes the structure of the second semiconductor chip 4 in detail.

At least on a surface facing the optical element 3, the second semiconductor chip 4 is provided with a reflection suppressing portion 12 which suppresses reflection of the light incident on the second semiconductor chip 4. As can be seen in FIG. 2C, light passing through the light-transmitting cover 7 is incident also on the second semiconductor chip 4. The incident light 11 is reflected by a side surface of the second semiconductor chip 4. If the reflected light is subsequently incident on the optical element 3 of the first semiconductor chip 2, the unwanted reflected light may cause functional degradation (e.g., image abnormality such as ghost and flare).

Accordingly, the reflection suppressing portion is provided on the side surface of the second semiconductor chip 4 for preventing light from being reflected by the second semiconductor chip 4 and incident on the first semiconductor chip 2.

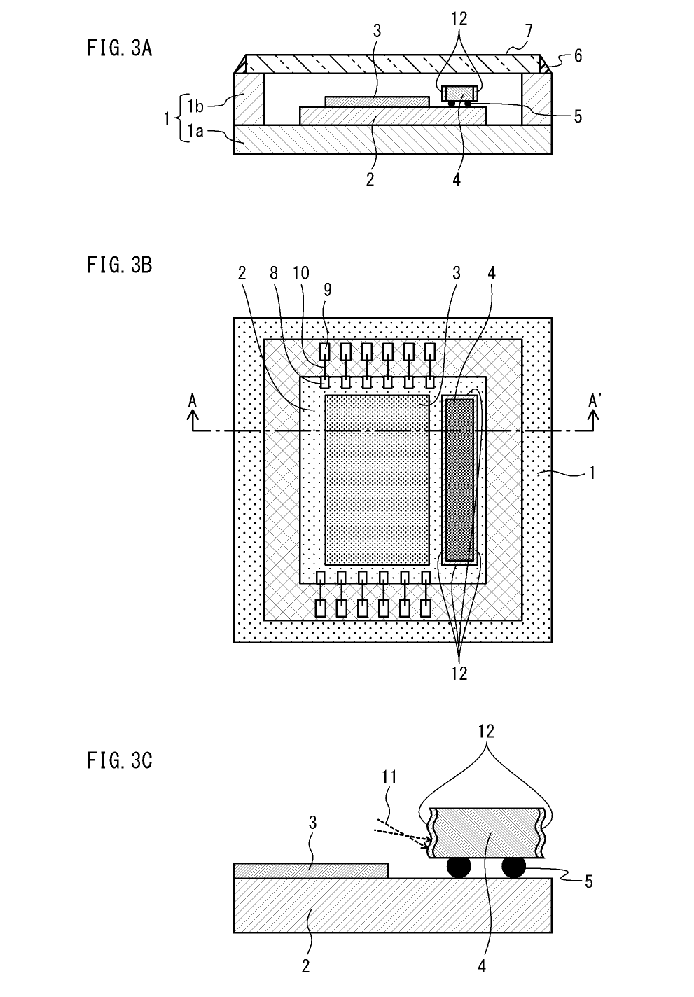

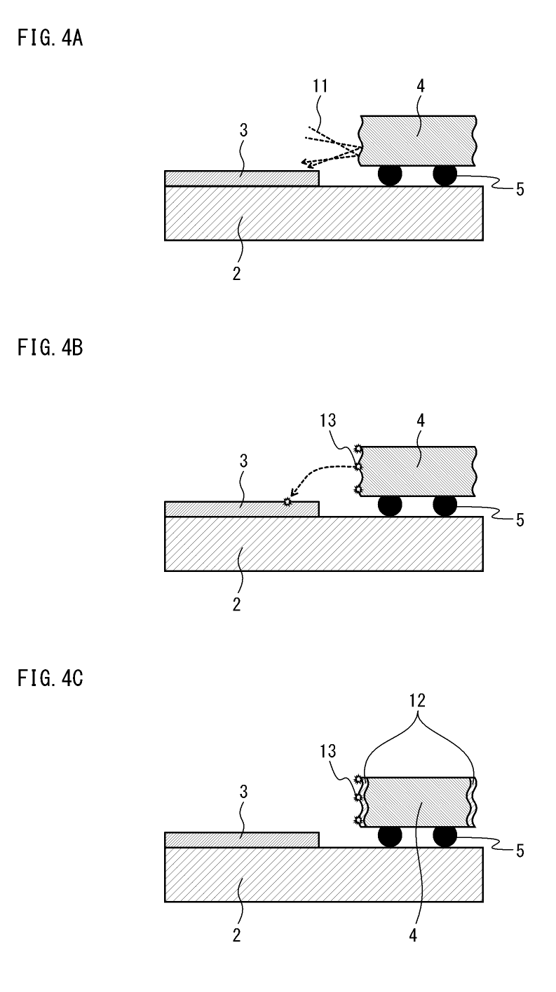

Note that the reflection suppressing portion 12 may be provided also on the opposite side surface, which faces away from the optical element 3. Alternatively, the reflection suppressing portion 12 may be provided on all side surfaces of the second semiconductor chip 4. The thus structured second semiconductor chip 4 is shown in FIG. 3A to FIG. 3C. With this structure, a designing process is omitted for determining the positional relation between the first semiconductor chip and the reflection suppressing portion.

Preferably, the reflection suppressing portion 12 should be made of a material having reflectivity lower than that of the material of the side surfaces of the second semiconductor chip 4. Specifically, it is preferable that the material having lower reflectivity should be (i) an acrylic resin or epoxy resin containing carbon black, iron black, or black titanium oxide, (ii) a sheet material containing carbon black, iron black, or black titanium oxide, or (iii) a black resin.

For reference, the following describes a second semiconductor chip having no reflection suppressing portion formed thereon with reference to FIG. 4A to FIG. 4C, which are partially enlarged views of the semiconductor module showing the second semiconductor chip facing the optical element and other elements in vicinity thereof.

As shown in FIG. 4A, since the second semiconductor chip 4 has no reflection suppressing portion, the incident light 11 is reflected by the side surface of the second semiconductor chip 4 and is subsequently incident on the optical element 3 of the first semiconductor chip 2. Consequently, the unwanted reflected light 11 causes functional degradation (e.g., image abnormality such as ghost and flare).

In addition, as shown in FIG. 4B, dust 13 derived from silicon, organic film, or the like may remain on the side surface of the second semiconductor chip 4. Since the second semiconductor chip 4 has no reflection suppressing portion, the dust 13 may remain on the side surface of the second semiconductor chip 4. Accordingly, the dust 13 may be transferred and deposited on the optical element 3, which leads to a high risk of malfunction. On the contrary, since the second semiconductor chip 4, as shown in FIG. 4C, has a reflection suppressing portion, the dust remaining on the side surface of the second semiconductor chip 4 is captured in the reflection suppressing portion 12. Accordingly, transfer of the dust to the optical element 3 is suppressed, which improves the yield and enables stable manufacturing.

(Variation 2)

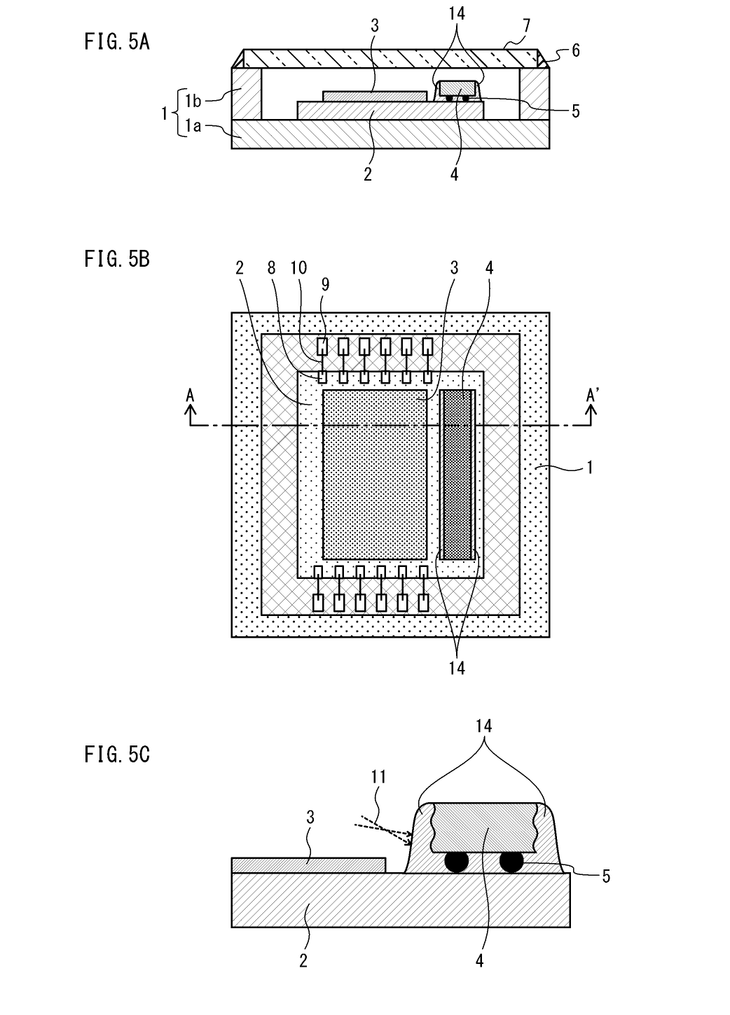

The following describes the general structure of a semiconductor module according to Variation 2 of the embodiment of the present disclosure with reference to FIG. 5A to FIG. 5C. FIG. 5A is a schematic sectional view of the semiconductor module. FIG. 5B is a top view showing the semiconductor module with the light-transmitting cover removed. FIG. 5C is a partially enlarged view of the semiconductor module showing the second semiconductor chip facing the optical element and other elements in vicinity thereof.

The structural elements in Variation 2 are the same as those in the embodiment except the second semiconductor chip 4. Therefore, description is omitted for the structural elements other than the second semiconductor chip 4, and the following describes the structure of the second semiconductor chip 4 in detail.

An underfill 14 is formed between the first semiconductor chip 2 and the second semiconductor chip 4. The underfill 14 contains a material which suppresses reflection of light incident on the second semiconductor chip 4. The presence of the underfill 14 enables suppression of reflection from the bottom surfaces of the second semiconductor chip 4.

As shown in FIG. 5A to FIG. 5C, the reflection suppressing portion may also be formed on the side surfaces of the second semiconductor chip 4 by extending the underfill 14 formed between the first semiconductor chip 2 and the second semiconductor chip 4. Alternatively, the reflection suppressing portion formed on the side surfaces of the second semiconductor chip may be made of other material than that used for the underfill 14.

Preferably, the underfill 14 should be made of a material having reflectivity lower than that of the material of the side surface of the second semiconductor chip 4. Specifically, it is preferable that the material having lower reflectivity should be (i) an acrylic resin or epoxy resin containing carbon black, iron black, or black titanium oxide, (ii) a sheet material containing carbon black, iron black, or black titanium oxide, or (iii) a black resin.

(Variation 3)

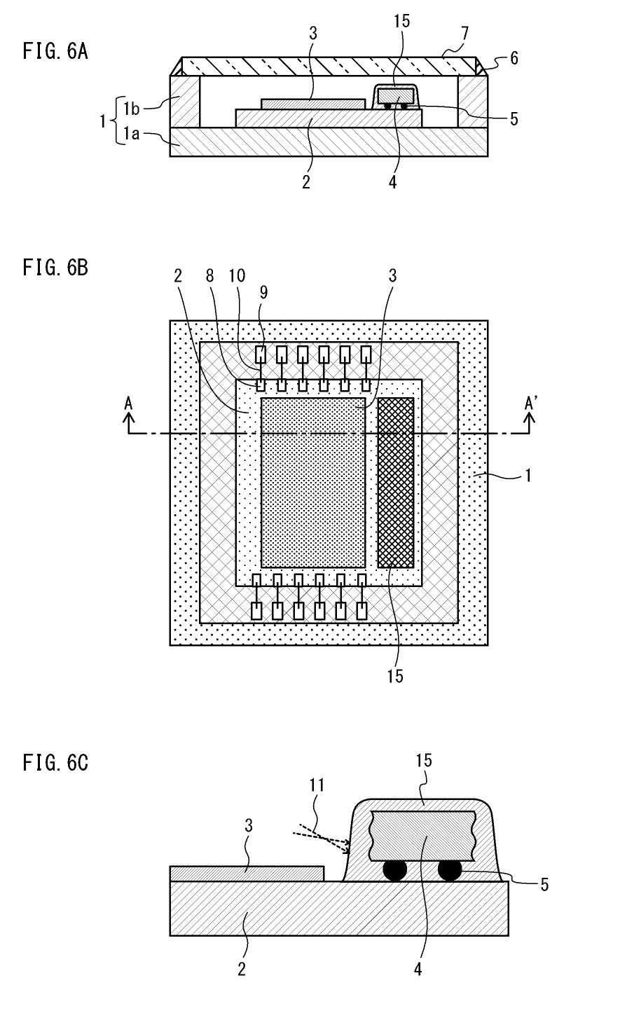

The following describes the general structure of a semiconductor module according to Variation 3 of the embodiment of the present disclosure with reference to FIG. 6A to FIG. 6C. FIG. 6A is a schematic sectional view of the semiconductor module. FIG. 6B is a top view showing the semiconductor module with the light-transmitting cover removed. FIG. 6C is a partially enlarged view of the semiconductor module showing the second semiconductor chip facing the optical element and other elements in vicinity thereof.

The structural elements in Variation 4 are the same as those in the embodiment except the second semiconductor chip 4. Therefore, description is omitted for the structural elements other than the second semiconductor chip 4, and the following describes the structure of the second semiconductor chip 4 in detail.

Here, the reflection suppressing portion, which suppresses reflection of light incident on the second semiconductor chip 4, is formed so as to cover the entire side surfaces and the entire top and bottom surfaces (i.e., all surfaces) of the second semiconductor chip 4. This can be achieved by applying potting material 15 having a reflection suppressing function.

Preferably, the potting material 15 should be made of a material having reflectivity lower than that of the material of the side surfaces of the second semiconductor chip 4. it is preferable that the material having lower reflectivity should be (i) an acrylic resin or epoxy resin containing carbon black, iron black, or black titanium oxide, (ii) a sheet material containing carbon black, iron black, or black titanium oxide, or (iii) a black resin.

(Variation 4)

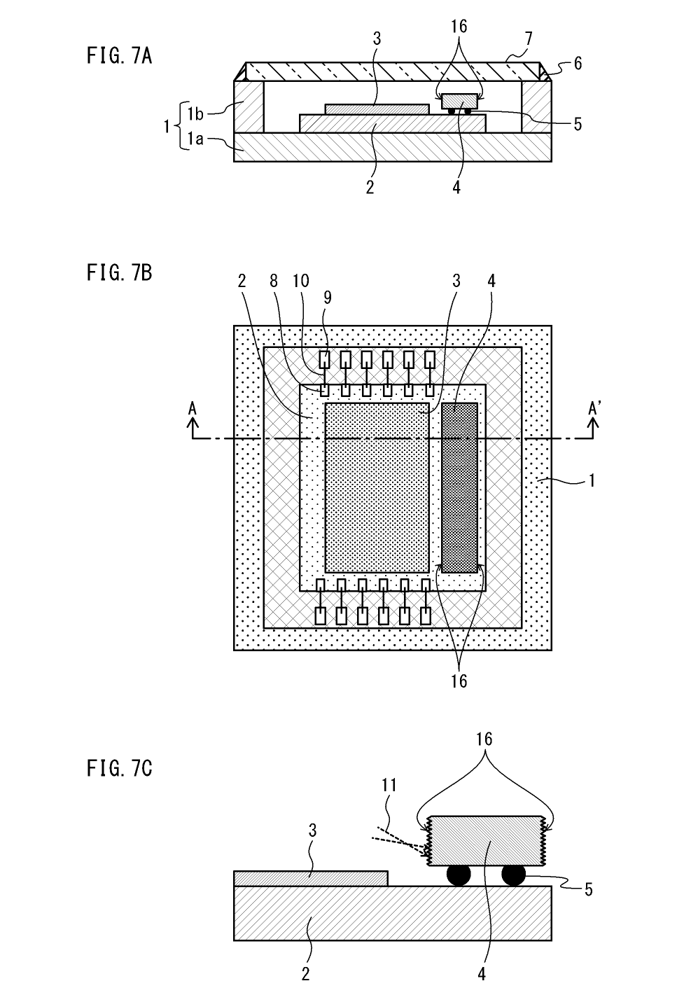

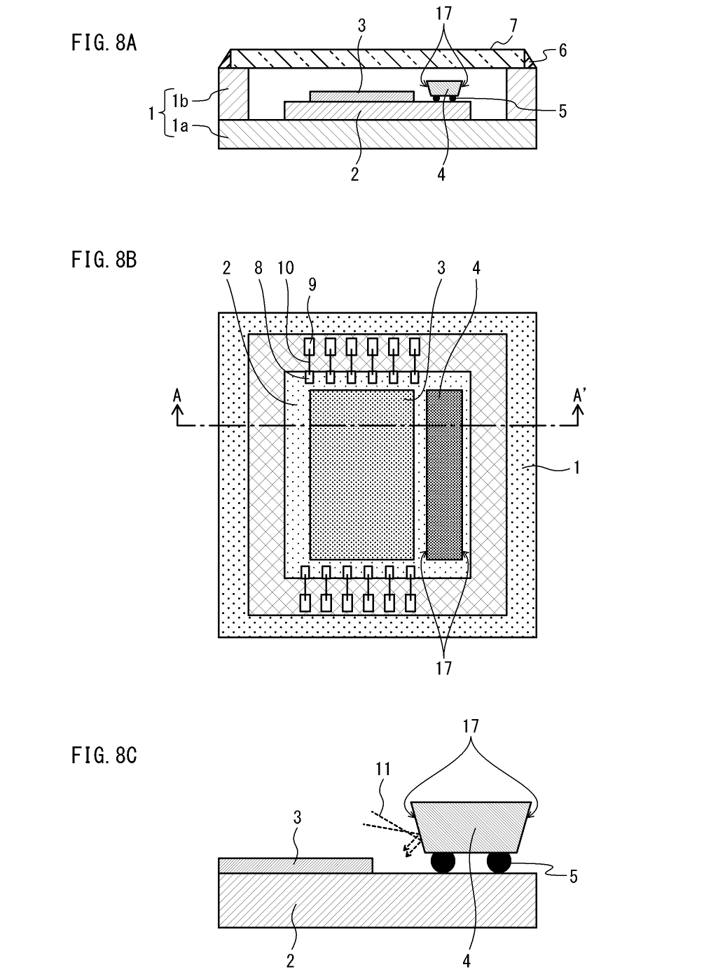

The following describes the general structure of a semiconductor module according to Variation 4 of the embodiment of the present disclosure with reference to FIG. 7A to FIG. 7C. FIG. 7A is a schematic sectional view of the semiconductor module. FIG. 7B is a top view showing the semiconductor module with the light-transmitting cover removed. FIG. 7C is a partially enlarged view of the semiconductor module showing the second semiconductor chip facing the optical element and other elements in vicinity thereof.

The structural elements in Variation 4 are the same as those in the embodiment except the second semiconductor chip 4. Therefore, description is omitted for the structural elements other than the second semiconductor chip 4, and the following describes the structure of the second semiconductor chip 4 in detail.

At least on a side surface facing the optical element 3, the second semiconductor chip 4 has a rough-surface portion 16 which suppresses reflection of light incident on the second semiconductor chip 4. The rough-surface portion 16 is formed by surface-treating the side surface so as to be rougher than the remaining surfaces. The remaining surfaces include the top and bottom surfaces of the second semiconductor chip 4. By forming the rough-surface portion 16 in this manner, an advantage is provided that dust left on the side surface of the second semiconductor chip 4 is removed and deposition of the dust on the optical element 3 is suppressed. In addition, since the surface is rough, light is prevented from being reflected and incident on the optical element as unwanted light. Preferably, the surface roughness should be adjusted so that light is prevented from being reflected and incident on the optical element as unwanted light.

The rough-surface portion 16 may be further provided on the opposite side surface to the side surface, which faces away from the optical element 3. Furthermore, the rough-surface portion 16 may be provided over the entire surfaces of the second semiconductor chip 4. With this structure, a designing process is omitted for determining the positional relation between the first semiconductor chip 2 and rough-surface portion 16.

(Variation 5)

The following describes the general structure of a semiconductor module according to Variation 5 of the embodiment of the present disclosure with reference to FIG. 8A to FIG. 8C. FIG. 8A is a schematic sectional view of the semiconductor module. FIG. 8B is a top view showing the semiconductor module with the light-transmitting cover removed. FIG. 8C is a partially enlarged view of the semiconductor module showing the second semiconductor chip facing the optical element and other elements in vicinity thereof.

The structural elements in Variation 5 are the same as those in the embodiment except the second semiconductor chip 4. Therefore, description is omitted for the structural elements other than the second semiconductor chip 4, and the following describes the structure of the second semiconductor chip 4 in detail.

Among the surfaces of the second semiconductor chip 4, the surface facing the first semiconductor chip 2 is referred to as the first surface, and the surface opposite the first surface is referred to as the second surface. The second semiconductor chip 4 is provided with tapered portions 17 each being tapered from the second surface to the first surface. The tapered portions 17 are formed by tapering the second semiconductor chip 4. By forming the tapered portions 17, the second semiconductor chip 4 has inclined side surfaces, which prevent light from being reflected and reaching the optical element 3 as unwanted light. It is preferable that the angle of inclination should be appropriately adjusted so that light reflected towards the optical element 3 as unwanted light is suppressed. Specifically, the angle between the top surface of the first semiconductor chip 2 and the tapered side surface of the second semiconductor chip 4 is determined so as to fall within the range of 10 to 80 degrees.

The inclined side surface of the second semiconductor chip 4 may be of a form other than the tapered portion 17. It suffices that the second semiconductor chip 4 has a shape in which the edge of the second surface on the side facing the optical element is positioned closer to the optical element than the edge of the first surface on the same side in the direction parallel to the top or bottom surface of the first semiconductor chip 2 shown in FIG. 8C. Alternatively, the second semiconductor chip 4 may be shaped so that the area of the first surface is smaller than that of the second surface.

With the second semiconductor chip 4 thus shaped to have the inclined side surfaces, an advantage is provided that light reflected by the second semiconductor chip 4 is less likely to reach the optical element 3.

(Variation 6)

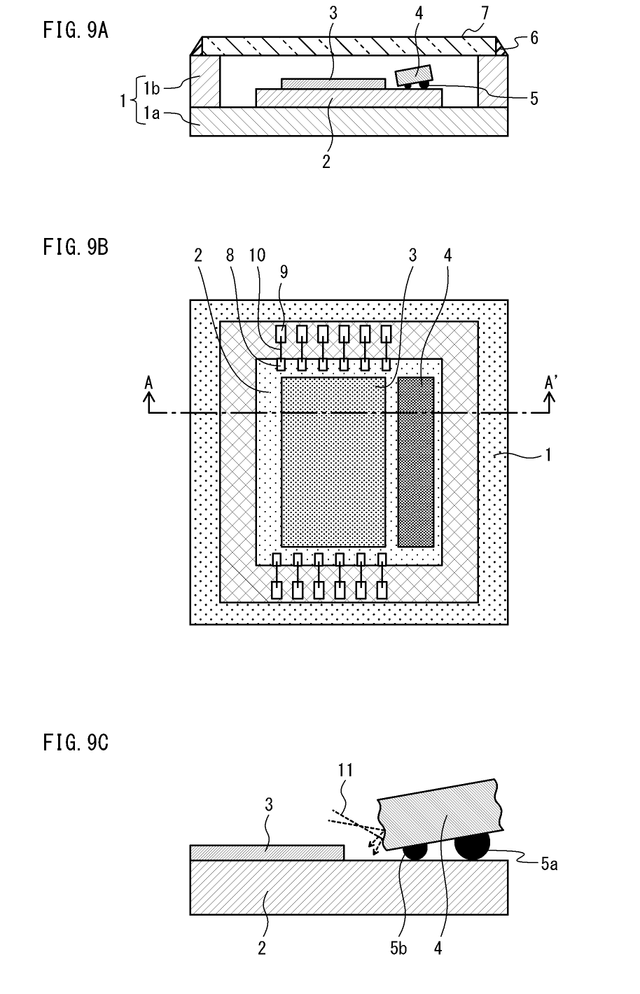

The following describes the general structure of a semiconductor module according to Variation 6 of the embodiment of the present disclosure with reference to FIG. 9A to FIG. 9C. FIG. 9A is a schematic sectional view of the semiconductor module. FIG. 9B is a top view showing the semiconductor module with the light-transmitting cover removed. FIG. 9C is a partially enlarged view of the semiconductor module showing the second semiconductor chip facing the optical element and other elements in vicinity thereof.

The structural elements in Variation 6 are the same as those in the embodiment except the second semiconductor chip 4. Therefore, description is omitted for the structural elements other than the second semiconductor chip 4, and the following describes the structure of the second semiconductor chip 4 in detail.

The second semiconductor chip 4 is arranged so that the gap between the first semiconductor chip 2 and the second semiconductor chip 4 is larger on the side closer to the optical element 3 than on the opposite side. For example, the second semiconductor chip 4 may be mounted on the first semiconductor chip at an angle. This is achieved by using a higher bump on the closer side than that on the opposite side. With this structure, the side surfaces of the second semiconductor chip 4 are inclined. It is preferable that the angle of inclination should be appropriately adjusted so that light reflected towards the optical element 3 as unwanted light is suppressed. Specifically, the angle between the top surface of the first semiconductor chip 2 and the side surfaces of the second semiconductor chip 4 is determined to fall within the range of 10 to 80 degrees.

With the above-mentioned structure, an advantage is provided that light reflected by the second semiconductor chip 4 is less likely to reach the optical element 3.

Note that various structural features of the above-mentioned embodiment and variations thereof may be combined as long as they are compatible. With such combinations, suppression is achieved more reliably for factors causing functional degradation, such as deposition of dust transferred from the side surface of the second semiconductor chip onto the optical element, and light which is reflected by the side surface of the second semiconductor chip and incident on the optical element.

### INDUSTRIAL APPLICABILITY

The semiconductor module according to the present disclosure enables overall miniaturization of a product having the semiconductor module mounted therein.

### REFERENCE SIGNS LIST

1 Casing
2 First semiconductor chip
3 Optical element
4 Second semiconductor chip
5 Bump
6 Adhesive
7 Light-transmitting cover
8 Electrode pad
9 Electrode pad
10 Wire
11 Incident light
12 Reflection suppressing portion
13 Dust
14 Underfill
15 Potting material
16 Rough-surface portion
17 Tapered portion
18 Third semiconductor chip

1. A semiconductor module, comprising:
a first semiconductor chip having an optical element mounted thereon;
a second semiconductor chip mounted over the first semiconductor chip;
a casing accommodating therein the first semiconductor chip and the second semiconductor chip and having an opening at a position corresponding to the optical element; and
a light-transmitting cover closing the opening of the casing, wherein
the second semiconductor chip has a reflection suppressing function of suppressing reflection of light incident thereon.

2. The semiconductor module of claim 1, wherein
the reflection suppressing function is achieved by a reflection suppressing portion of the second semiconductor chip provided on a side surface thereof facing the optical element.

3. The semiconductor module of claim 1, wherein
the reflection suppressing function is achieved by an underfill which is disposed between the first semiconductor chip and the second semiconductor chip, the underfill containing a reflection suppressing material.

4. The semiconductor module of claim 1, wherein
the reflection suppressing function is achieved by a reflection suppressing portion provided on an entire periphery of the second semiconductor chip.

5. The semiconductor module of claim 1, wherein
the reflection suppressing function is achieved by a reflection suppressing portion provided on the second semiconductor chip, the reflection suppressing portion containing a material having reflectivity lower than reflectivity of a side surface of the second semiconductor chip.

6. The semiconductor module of claim 5, wherein
the material having lower reflectivity is an (i) acrylic resin or epoxy resin containing one of carbon black, iron black, and black titanium oxide, or a (ii) black resin.

7. The semiconductor module of claim 5, wherein
the material having lower reflectivity is a sheet material containing one of carbon black, iron black, and black titanium oxide.

8. The semiconductor module of claim 1, wherein
the reflection suppressing function is achieved by a rough-surface portion of the second semiconductor chip on a side surface thereof facing the optical element, the rough-surface portion presenting a surface rougher than remaining surfaces.

9. The semiconductor module of claim 1, wherein
the second semiconductor chip has a first surface facing the first semiconductor chip and a second surface opposite to the first surface, and
the second surface has an area smaller than an area of the first surface.

10. The semiconductor module of claim 1, wherein
the second semiconductor chip has a first surface facing the first semiconductor chip and a second surface opposite to the first surface, and
an edge of the second surface facing the optical element is positioned closer to the optical element than an edge of the first surface facing the optical element.

11. The semiconductor module of claim 1, wherein
the second semiconductor chip has a first surface facing the first semiconductor chip and a second surface opposite to the first surface, and
the second semiconductor chip has a side surface tapered from the second surface to the first surface.

12. The semiconductor module of claim 1, wherein
a gap between the first semiconductor chip and the second semiconductor chip is larger on a side close to the optical element than on a side away from the optical element.

13. The semiconductor module of claim 1, wherein
the casing has a recess at a position under the first semiconductor chip, and
a third semiconductor chip is mounted in the recess.

14. The semiconductor module of claim 1, further comprising
a third semiconductor chip mounted on the first semiconductor chip.

15. The semiconductor module of claim 1, wherein
the second semiconductor chip is mounted over the first semiconductor chip so as to overlap the optical element only partially or not at all in plan view.
